(19) United States
(12) Patent Application Publication
(10) Pub. No.: US 2022/0319921 A1
(43) Pub. Date: Oct. 6, 2022

(54) Semiconductor Structure and Method for Manufacturing Semiconductor Structure

(71) Applicant: CHANGXIN MEMORY TECHNOLOGIES, INC., Hefei City (CN)

(72) Inventors: Mengmeng YANG, Hefei City (CN); Xiaoling Wang, Hefei City (CN)

(21) Appl. No.: 17/650,296

(22) Filed: Feb. 8, 2022

Related U.S. Application Data
(63) Continuation of application No. PCT/CN2021/111485, filed on Aug. 9, 2021.

(30) Foreign Application Priority Data
Apr. 2, 2021 (CN) 202110362860.X

(51) Int. Cl. H01L 21/768; H01L 23/528; H01L 23/535; H01L 21/311

(52) U.S. Cl. CPC H01L 21/76895; H01L 23/5283; H01L 23/535; H01L 21/31116; H01L 21/76805; H01L 21/76843

(57) ABSTRACT

The present disclosure relates to a semiconductor structure and a method for manufacturing a semiconductor structure. The method includes: providing a substrate, interlayer dielectric layer and conductive structures located in the interlayer dielectric layer being formed on the substrate; forming a first isolation dielectric layer on the interlayer dielectric layer and the conductive structures; forming trenches in the first isolation dielectric layer, the trenches exposing upper surfaces and parts of side walls of the conductive structures; and filling in the trenches to form conductive layer structure; and the distance between a bottom side wall of each trench and an exposed side wall of each conductive structure is a first preset value, and the distance between the bottom of each trench and the upper surface of each conductive structure is a second preset value.

### CROSS-REFERENCE TO RELATED APPLICATION

The present disclosure is a continuation of International Patent Application PCT/CN2021/111485, filed on Aug. 9, 2021, which claims the priority of Chinese Patent Application No. 202110362860.X, filed to the China National Intellectual Property Administration on Apr. 2, 2021 and entitled “Semiconductor Structure and Method for Manufacturing Semiconductor Structure”. International Patent Application PCT/CN2021/111485 and Chinese Patent Application No. 202110362860.X are incorporated herein by reference in their entireties.

### TECHNICAL FIELD

The present disclosure relates to the technical field of semiconductors, and in particular, to a semiconductor structure and a method for manufacturing a semiconductor structure.

### BACKGROUND

During a method for manufacturing a typical semiconductor structure, in order to overcome a effect of a process variation on the alignment of upper and lower contact holes, and to ensure that a first conductive material in a first contact hole corresponding to an upper conductive structure fully contacts a second conductive material in a second contact hole corresponding to a lower conductive structure, a feature size of the first contact hole is set to be greater than a feature size of the second contact hole, and when etching is performed to form the first contact hole, the etching stops at an upper surface of the second conductive material so as to expose the upper surface of the second conductive material, so that the first conductive material filled in the first contact hole forms a good contact with the second conductive material.

However, there is a certain deviation in etching rates of etching the second conductive material and etching an interlayer dielectric layer in the second conductive material, and in order to ensure that the upper surface of the second conductive material can be completely exposed, some etching time is generally increased, so that when the second conductive material is etched to expose, a part of side walls of the second conductive material is exposed, and small grooves are formed between exposed side walls and the interlayer dielectric layer, which renders that incomplete filling of the first conductive material subsequently filled easily occurs at the grooves, thereby forming a void defect, and further affecting a contact between the first conductive material and the second conductive material, increasing a contact resistance between the first conductive material and the second conductive material, and affecting conductive performance between the first conductive material and the second conductive material.

### SUMMARY

According to various embodiments of the present disclosure, a semiconductor structure and a method for manufacturing a semiconductor structure are provided.

Some embodiments of the present disclosure provide a method for manufacturing a semiconductor structure, including:

a substrate is provided, an interlayer dielectric layer being formed on the substrate and at least one conductive structure located in the interlayer dielectric layer;

a first isolation dielectric layer is formed on the interlayer dielectric layer and the at least one conductive structure;

at least one trench is formed in the first isolation dielectric layer, one of the trench exposing an upper surface and a part of side walls of the at least one conductive structure; and

the trench is filled to form a first conductive layer structure;

and a distance between a bottom side wall of the trench and an exposed side wall of the conductive structure is a first preset value, and the bottom side wall of the trench and the exposed side wall of the conductive structure are on a same side, and a distance between a bottom of the trench and the upper surface of the conductive structure is a second preset value.

Some embodiments of the present disclosure further provide a semiconductor structure, the semiconductor structure including:

at least one conductive layer structure, the at least one conductive layer structure being obtained by the method for manufacturing the semiconductor structure according to any one above.

### BRIEF DESCRIPTION OF THE DRAWINGS

In order to illustrate the technical solutions of the embodiments of the present disclosure or conventional techniques more clearly, hereinafter, accompanying drawings requiring to be used in the description of the embodiments or conventional techniques will be briefly introduced. Apparently, the accompanying drawings in the following description merely relate to some embodiments of the present disclosure, and for a person of ordinary skill in the art, other accompanying drawings can also be obtained according to these accompanying drawings without involving any inventive effort.

FIG. 1 is a schematic flowchart of a method for manufacturing a semiconductor structure in some embodiments;

FIG. 2 is a schematic cross-sectional diagram of the semiconductor structure after a photoresist mask pattern is formed in some embodiments;

FIG. 3 is a schematic flowchart of forming at least one trench in a first isolation dielectric layer in some embodiments;

FIG. 4 is a schematic flowchart of patterning the first isolation dielectric layer by the photoresist mask pattern as a mask in some embodiments;

FIG. 5 is a schematic flowchart of forming a mask layer on the first isolation dielectric layer in some embodiments;

FIG. 6 is a schematic cross-sectional diagram of the semiconductor structure after a mask pattern is formed in some embodiments;

FIG. 7 is a schematic cross-sectional diagram of the semiconductor structure after the trench is formed in some embodiments;

FIG. 8 is a schematic cross-sectional diagram of the semiconductor structure after the trench is formed in some other embodiments;

FIG. 9 is a schematic cross-sectional diagram of the semiconductor structure corresponding to FIG. 7 after the first conductive layer structure is formed in some embodiments;

FIG. 10 is a schematic flowchart of filling the trench to form the first conductive layer structure in some embodiments;

FIG. 11 is a schematic flowchart of a method for manufacturing a semiconductor structure in some other embodiments; and

FIG. 12 is a schematic cross-sectional diagram of a semiconductor structure after a second conductive layer structure is formed in some embodiments.

### DETAILED DESCRIPTION OF THE EMBODIMENTS

For ease of understanding of some embodiments of the present disclosure, hereinafter, some embodiments of the present disclosure will be described more comprehensively with reference to the related accompanying drawings. Preferred embodiments of the present disclosure are given in the accompanying drawings. However, some embodiments of the present disclosure may be implemented in many different forms, and are not limited to the embodiments described herein. Rather, the purpose of providing these embodiments is to enable the content disclosed in some embodiments of the disclosure to be thorough and complete.

Unless otherwise defined, all technical and scientific terms used herein have the same meanings as those commonly understood by a person skilled in the art to which the present disclosure belongs. Herein, the terms used in the description of the present disclosure are for the purpose of describing particular embodiments only, and are not intended to limit some embodiments of the present disclosure.

It will be understood that when an element or layer is referred to as being “on . . . ”, “adjacent to . . . ”, “connected to” or “coupled to” other elements or layers, it can be directly on, adjacent to, connected to or coupled to the other elements or layers, or intermediate elements or layers may be present. In contrast, when an element is referred to as being “directly on . . . ”, “directly adjacent to . . . ”, “directly connected to” or “directly coupled to” other elements or layers, there are no intermediate elements or layers. It will be understood that although terms first, second, third, etc., may be used to describe various elements, components, regions, layers, doping types and/or portions, these elements, components, regions, layers, doping types and/or portions should not be limited by these terms. These terms are only used to distinguish one element, component, region, layer, doping type or portion from another element, component, region, layer, doping type or portion. Thus, a first element, component, region, layer, doping type or portion discussed below could be represented as a second element, component, region, layer or portion without departing from the teachings of some embodiments of the present disclosure. For example, a first doping type may be made a second doping type, and similarly, a second doping type may be made a first doping type; and the first doping type and the second doping type are different doping types, for example, the first doping type may be P-type and the second doping type may be N-type, or the first doping type may be N-type and the second doping type may be P-type.

Spatial relationship terms, such as “under . . . ”, “below . . . ”, “lower”, “beneath . . . ”, “above . . . ”, “upper” etc., may be used herein to describe the relationship between one element or feature and other elements or features as shown in the figures. It will be understood that in addition to the orientations shown in the figures, the spatial relationship terms further include different orientations of a device in use and operation. For example, if a device in the figures is turned over, elements or features described as “under” or “beneath” or “below” other elements would then be oriented “above” the other elements or features. Thus, the exemplary terms “below . . . ” and “under . . . ” may include both an upper orientation and a lower orientation. In addition, the device may include additional orientations (e.g., rotated by 90 degrees or other orientations), and spatial description phrases used herein are interpreted accordingly.

As used herein, the singular forms “a”, “an”, and “said/the” may include plural forms as well, unless the context clearly indicates otherwise. It will be further understood that the terms “composed of” and/or “include”, when used in this description, can specify the presence of stated features, integers, steps, operations, elements, and/or components, but do not preclude the presence or addition of one or more other features, integers, steps, operations, elements, components, and/or groups. Also, as used herein, the term “and/or” includes any and all combinations of the associated listed items.

Herein, embodiments of the disclosure are described with reference to cross-sectional diagrams as schematic diagrams of embodiments (and intermediate structures) of the present disclosure; in this way, variations in the shown shapes caused by for example, manufacturing techniques and/or tolerances may be contemplated. Accordingly, embodiments of the present disclosure should not be limited to the particular shapes of regions illustrated herein, but include deviations in shapes caused by for example, manufacturing techniques. For example, an implanted region shown to be a rectangle generally has rounded or curved features and/or implanted gradient concentrations at edges thereof, rather than a binary change from an implanted region to a non-implanted region. Likewise, a buried region formed by implantation may lead to some implantation in a region between the buried region and a passing surface when the implantation is performed. Therefore, the regions shown in the figures are schematic in nature, their shapes do not represent actual shapes of the regions of a device, and do not limit the scope of some embodiments of the present disclosure.

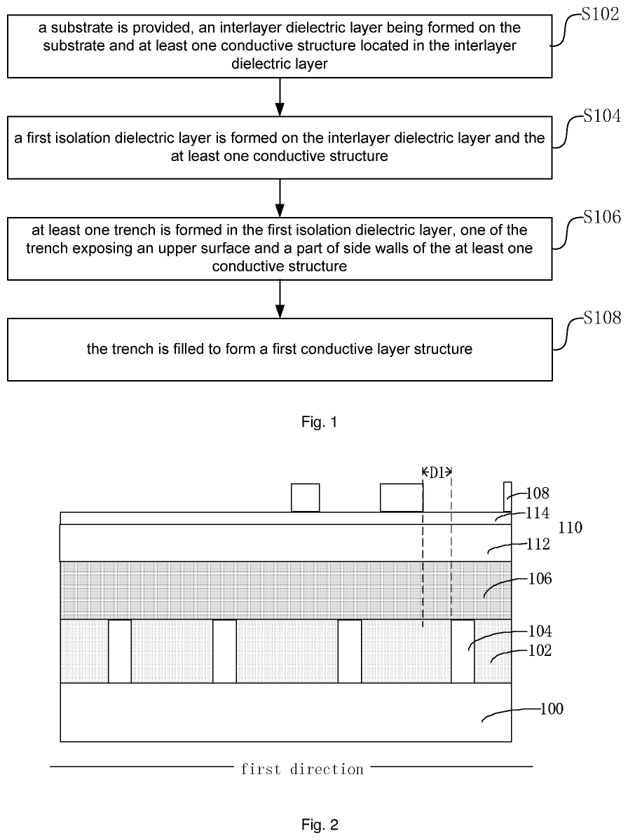

Refer to FIG. 1, FIG. 1 is a schematic flowchart of a method for manufacturing a semiconductor structure in some embodiments.

In some embodiments, some embodiments of the present disclosure provide the method for manufacturing the semiconductor structure. As shown in FIG. 1, the method includes:

S102, a substrate is provided, an interlayer dielectric layer being formed on the substrate and at least one conductive structure located in the interlayer dielectric layer.

Specifically, the substrate is provided, and an interlayer dielectric layer is formed on the substrate and the at least one conductive structure located in the interlayer dielectric layer. The substrate can adopt undoped monocrystalline silicon, monocrystalline silicon doped with impurities, silicon on insulator (SOI), stacked silicon on insulator (SSOI), stacked silicon germanium on insulator (S-SiGeOI), silicon germanium on insulator (SiGeOI) and germanium on insulator (GeOI), etc. As an example, in this embodiment, a constituent material of the substrate is selected from monocrystalline silicon.

S104, a first isolation dielectric layer is formed on the interlayer dielectric layer and the at least one conductive structure.

Specifically, the first isolation dielectric layer is formed on the substrate, and the first isolation dielectric layer covers the interlayer dielectric layer and the at least one conductive structure, for example, the first isolation dielectric layer covers upper surfaces of the interlayer dielectric layer and the at least one conductive structure.

S106, at least one trench is formed in the first isolation dielectric layer, one of the trench exposing an upper surface and a part of side walls of the at least one conductive structure.

Specifically, the trench exposing the upper surface of the conductive structure and the part of side walls of the conductive structure is formed in the first isolation dielectric layer, that is, a bottom of the trench is lower than the upper surface of the conductive structure, and the trench includes a part located above the conductive structure and a part located at two sides of the conductive structure; and the distance between the bottom side wall of the trench and the exposed side wall of the conductive structure is the first preset value, and the distance between the bottom of the trench and the upper surface of the conductive structure is the second preset value.

S108, the trench is filled to form a first conductive layer structure.

Specifically, the trench is filled to form the first conductive layer structure, and a lower surface of the first conductive layer structure is in contact connection with the upper surface and the part of side walls of the conductive structure, that is, a contact surface between the first conductive layer structure and the conductive structure is an inverted plug-type structure.

In the described method for manufacturing the semiconductor structure, the trench exposing the upper surface and the part of side walls of the at least one conductive structure is formed in the first isolation dielectric layer on the substrate, and then the trench is filled to form the first conductive layer structure, and the distance between the side wall of the trench and the side wall of the conductive structure is the first preset value, and the distance between the bottom of the trench and the upper surface of the conductive structure is the second preset value, so that the first conductive layer structure can completely fill the trench and completely contact the conductive structure, and contact areas between the first conductive layer structure and the conductive structure are increased, and a contact resistance is reduced; in addition, a contact surface between the first conductive layer structure and the conductive structure is an inverted plug-type structure, and contact stability between the first conductive layer structure and the conductive structure is increased.

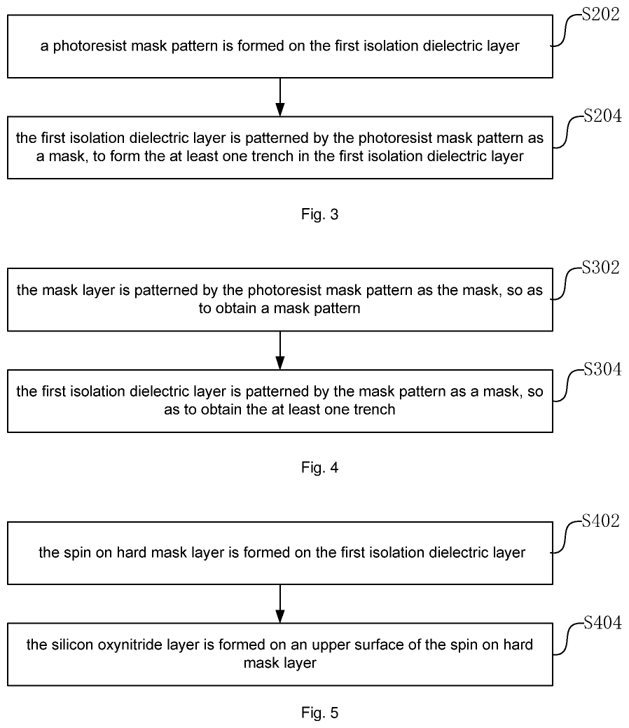

Refer to FIG. 2, FIG. 2 is a schematic cross-sectional diagram of a semiconductor structure after a photoresist mask pattern is formed in some embodiments. Refer to FIG. 3, FIG. 3 is a schematic flowchart of forming the at least one trench in the first isolation dielectric layer in some embodiments. Refer to FIG. 4, FIG. 4 is a schematic flowchart of patterning the first isolation dielectric layer by the photoresist mask pattern as a mask in some embodiments. Refer to FIG. 5, FIG. 5 is a schematic flowchart of forming a mask layer on the first isolation dielectric layer in some embodiments.

As shown in FIG. 2, first, the substrate 100 is acquired, and the interlayer dielectric layer 102 and the at least one conductive structure 104 located in the interlayer dielectric layer 102 is formed on the substrate 100. In some embodiments, lower surfaces of the interlayer dielectric layer 102 and the conductive structure 104 are flush with an upper surface of the substrate 100, and the upper surface of the conductive structure 104 is flush with the upper surface of the interlayer dielectric layer 102. Secondly, the first isolation dielectric layer 106 is formed on the substrate 100, and the first isolation dielectric layer 106 covers the interlayer dielectric layer 102 and the conductive structure 104, and the first isolation dielectric layer 106 covers the upper surface of the interlayer dielectric layer 102 and the upper surface of the conductive structure 104, or there are other device structures between the lower surface of the first isolation dielectric layer 106, and the upper surface of the interlayer dielectric layer 102 and the upper surface of the conductive structure 104. Hereinafter, the method for manufacturing the semiconductor structure is described by taking, as an example, the first isolation dielectric layer 106 covering the upper surface of the interlayer dielectric layer 102 and the upper surface of the conductive structure 104.

As shown in FIGS. 2 and 3, in some embodiments, the at least one trench is formed in the first isolation dielectric layer 106 includes:

S202, a photoresist mask pattern is formed on the first isolation dielectric layer.

Specifically, the photoresist mask pattern 108 is formed on the first isolation dielectric layer 106, a projection of a opening of the photoresist mask pattern 108 on the substrate 100 covers the conductive structure 104, and a distance between a side wall of the opening of the photoresist mask pattern and a side wall of the conductive structure 104 in a direction is greater than or equal to the first preset value, the direction is parallel to a surface of the substrate. That is, a horizontal distance D1 between the side wall of the opening of the photoresist mask pattern 108 and the side wall of the conductive structure 104 in a first direction is greater than zero, and D1 is greater than or equal to the distance (the first preset value) between the bottom side wall of the trench and the exposed side wall of the conductive structure 104 in the first direction.

S204, the first isolation dielectric layer is patterned by the photoresist mask pattern as a mask, to form the at least one trench in the first isolation dielectric layer.

As shown in FIGS. 2 and 4, in some embodiments, before step S202, the method further includes:

a mask layer 110 is formed on the first isolation dielectric layer 106; and

step S204 includes:

S302, the mask layer is patterned by the photoresist mask pattern as the mask, so as to obtain a mask pattern; and

S304, the first isolation dielectric layer is patterned by the mask pattern as a mask, so as to obtain the at least one trench.

As shown in FIGS. 2 and 5, in some embodiments, the mask layer 110 includes a spin on hard mask layer 112 and a silicon oxynitride layer 114 stacked in sequence on the first isolation dielectric layer 106. the mask layer 110 is formed on the first isolation dielectric layer 106 includes:

S402, the spin on hard mask layer is formed on the first isolation dielectric layer.

Specifically, the spin on hard mask layer 112 (SOH: Spin On Hard) is formed on the first isolation dielectric layer 106 by a spin coating process well known to a person skilled in the art. In some embodiments, the spin on hard mask layer 112 is in contact with an upper surface of the first isolation dielectric layer 106.

S404, the silicon oxynitride layer is formed on an upper surface of the spin on hard mask layer.

Specifically, the silicon oxynitride layer 114 is formed on the upper surface of the spin on hard mask layer 112 by a film forming process well known to a person skilled in the art, such as a chemical vapor deposition process, a physical vapor deposition process, an atomic layer deposition process, etc.

In some embodiments, the mask layer 110 is patterned by the photoresist mask pattern 108 as the mask further includes:

the photoresist mask pattern 108 is removed; and

the first isolation dielectric layer 106 is patterned by the mask pattern as the mask further includes:

the mask pattern is removed.

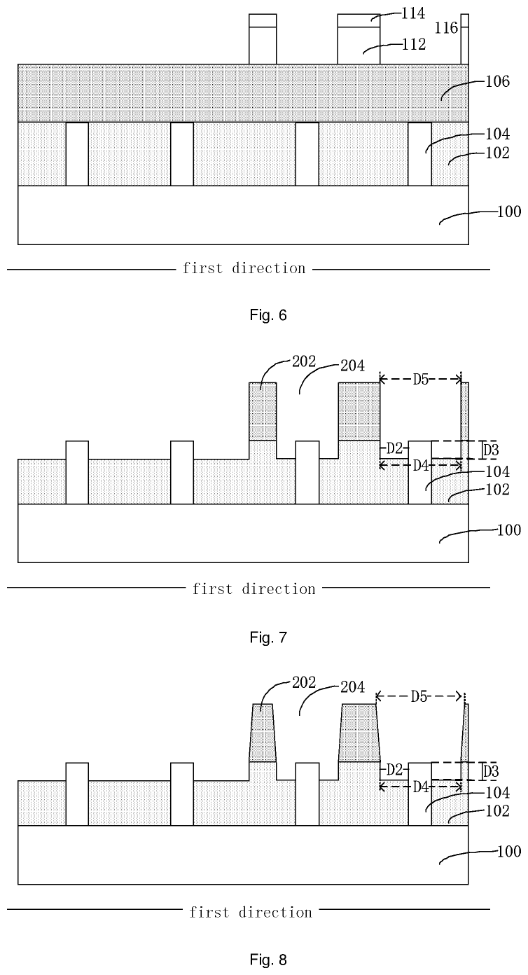

Refer to FIG. 6, FIG. 6 is a schematic cross-sectional diagram of the semiconductor structure after the mask pattern is formed in some embodiments. Refer to FIG. 7, FIG. 7 is a schematic cross-sectional diagram of the semiconductor structure after the trench is formed in some embodiments. Refer to FIG. 8, FIG. 8 is a schematic cross-sectional diagram of the semiconductor structure after the trench is formed in some other embodiments.

As shown in FIGS. 2, 6, 7 and 8, in a first step, the silicon oxynitride layer 114 and the spin on hard mask layer 112 in the mask layer 110 are sequentially patterned by the photoresist mask pattern 108 as the mask, the silicon oxynitride layer 114 and the spin on hard mask layer 112 not covered by the photoresist mask pattern 108 are removed, so as to obtain the mask pattern 116 composed of a remaining silicon oxynitride layer 114 and a remaining spin on hard mask layer 112. In this case, a pattern of the mask pattern 116 is the same as a pattern of the photoresist mask pattern 108. The photoresist mask pattern 108 on the mask patter 116 is removed, and the photoresist mask pattern 108 can be completely removed in the process of patterning the silicon oxynitride layer 114 and the spin on hard mask layer 112, and can also be completely removed by a process after the mask pattern 116 is formed. In this case, a schematic cross-sectional diagram of the semiconductor structure is as shown in FIG. 6. In a second step, the first isolation dielectric layer 106 is patterned by the mask pattern 116 as the mask, the first isolation dielectric layer 106 not covered by the mask pattern 116 and a part of the interlayer dielectric layer 102 located at two sides of the conductive structure 104 are removed, so as to obtain the first interlayer dielectric layer 202 composed of a remaining first isolation dielectric layer 106, and the trench 204 is formed in the first isolation dielectric layer 106 and the interlayer dielectric layer 102, and a distance D2 between the bottom side wall of the trench 204 and the exposed side wall of the conductive structure 104 is the first preset value, and a distance D3 between the bottom of the trench 204 and the upper surface of the conductive structure 104 is the second preset value; and the mask pattern 116 is removed, and the mask pattern 116 can be completely removed in a process of forming the trench 204, and can also be completely removed by a process after the trench 204 is formed. In this case, a schematic cross-sectional diagram of the semiconductor structure is as shown in FIG. 7 or 8.

In some embodiments, the first preset value D2 is not less than 3 nm and not greater than 10 nm, for example, 4 nm, 5 nm, 6 nm, 7 nm, 8 nm, etc., and the data above is only examples. In practical embodiments, the first preset value D2 is set according to practical requirements.

In some embodiments, the second preset value D3 is not less than 1 nm and not greater than 20 nm, for example, 4 nm, 5 nm, 6 nm, 7 nm, 8 nm, 10 nm, 13 nm, 15 nm, 18 nm, etc., and the data above is only examples. In practical embodiments, the second preset value D3 is set according to practical requirements.

In some embodiments, a distance D4 between bottom side walls of the trench 204 is not greater than a distance D5 between top side walls of the trench 204.

In some embodiments, the trench 204 at least includes one of an inverted trapezoidal trench and a rectangular trench. Specifically, when the distance D4 between the bottom side walls of the trench 204 is equal to the distance D5 between the top side walls of the trench 204, a cross section of the trench 204 in the first direction is the rectangular trench having a same width from top to bottom, and a schematic cross-sectional diagram of the semiconductor structure is as shown in FIG. 7; and when the distance D4 between the bottom side walls of the trench 204 is less than the distance D5 between the top side walls of the trench 204, a cross section of the trench 204 in the first direction is the inverted trapezoidal trench wide at the top and narrow at the bottom, so as to reduce difficulty of subsequent filling the trench 204 to form the first conductive layer structure, avoid formation of a void defect in the first conductive layer structure, increase a contact area between the upper surface of the first conductive layer structure 206 and another first conductive layer structure thereon, and reduce a contact resistance. A schematic cross-sectional diagram of the semiconductor structure is as shown in FIG. 8. Hereinafter, a cross-section of the trench 204 in the first direction being the rectangular trench having the same width from top to bottom will be described as an example.

In some embodiments, the trench 204 is formed by a dry etching process, and a process gas of the dry etching process includes a fluorine-based gas.

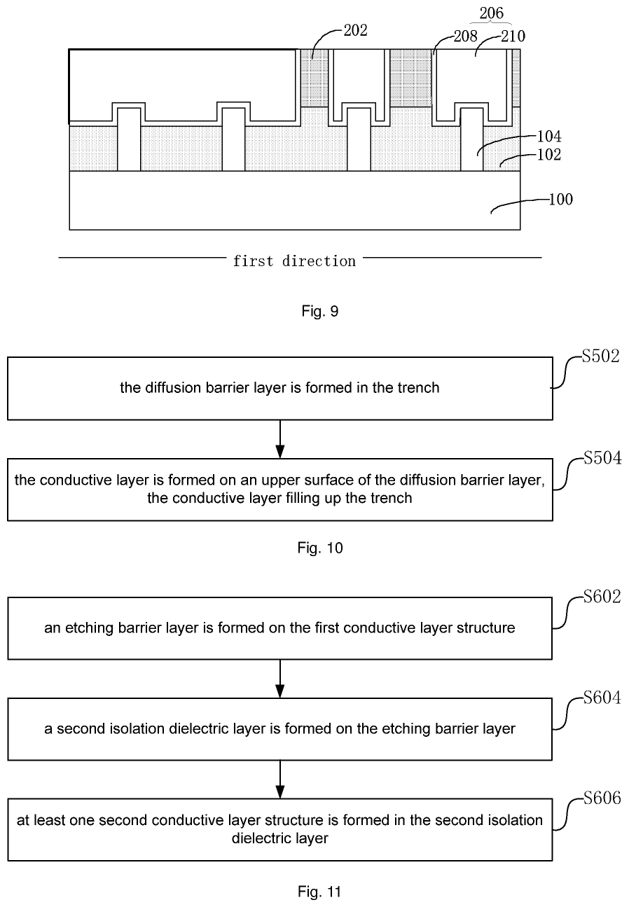

Refer to FIG. 9, FIG. 9 is a schematic cross-sectional diagram of the semiconductor structure corresponding to FIG. 7 after the first conductive layer structure is formed in some embodiments. Refer to FIG. 10, FIG. 10 is a schematic flowchart of filling trench to form the first conductive layer structure in some embodiments.

As shown in FIG. 9, after forming the at least one trench 204, the trench 204 is filled to form the first conductive layer structure 206.

As shown in FIGS. 9 and 10, in some embodiments, the first conductive layer structure 206 includes a diffusion barrier layer 208 and a conductive layer 210. Step S108 includes:

S502, the diffusion barrier layer is formed in the trench.

Specifically, first, a diffusion barrier material layer is formed in the trench 204, and the diffusion barrier material layer covers side walls of the trench 204, the bottom of the trench 204, the upper surfaces of the conductive structure 104 exposed by the trench 204, and side walls of the conductive structure 104 exposed by the trench 204, and extends to cover the interlayer dielectric layer 102. Then, a redundant diffusion barrier material layer is removed by etching, so as to obtain the diffusion barrier layer 208 formed by a remaining diffusion barrier material layer covering the side walls of the trench 204, the bottoms of the trench 204, the upper surface of the conductive structure 104 exposed by the trench 204, and the side walls of the conductive structure 104 exposed by the trench 204, and the diffusion barrier layer 208 do not fill up the trench 204.

S504, the conductive layer is formed on an upper surface of the diffusion barrier layer, the conductive layer filling up the trench.

Specifically, the conductive layer 210 filling up the trench 204 is formed on the upper surface of the diffusion barrier layer 208 by a film forming process.

In some embodiments, an upper surface of the conductive layer 210 in the trench 204 is higher than the upper surface of the first isolation dielectric layer 106 (the upper surface of the first interlayer dielectric layer 202). After step S504, the method further includes:

a thinning treatment is performed, until the upper surface of the conductive layer 210 is flush with the upper surface of the first isolation dielectric layer 106. For example, the conductive layer 210 located above the upper surface of the first isolation dielectric layer 106 is removed by chemical planarization processing.

In some embodiments, the diffusion barrier layer 208 at least include one of a titanium nitride material layer, a tantalum nitride material layer, and a tungsten nitride material layer, and the conductive layer 210 and the conductive structure 104 at least include one of a copper material layer, a tungsten material layer, and an aluminum material layer, or the conductive layer at least includes one of the copper material layer, the tungsten material layer and the aluminum material layer, or the conductive structure at least includes one of the copper material layer, the tungsten material layer and the aluminum material layer.

In some embodiments, the interlayer dielectric layer 102 and the first isolation dielectric layer 106 include silicon oxide material layer respectively.

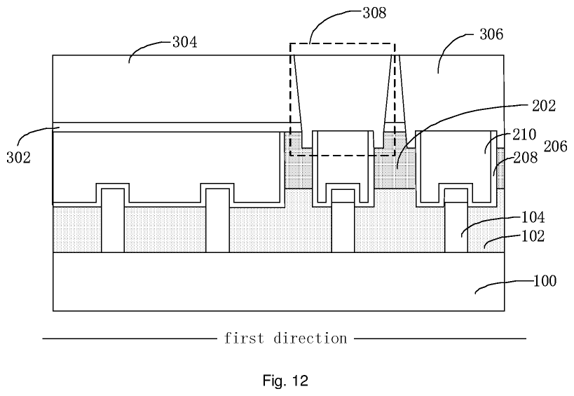

Refer to FIG. 11, FIG. 11 is a schematic flowchart of the method for manufacturing the semiconductor structure in some other embodiments. Refer to FIG. 12, FIG. 12 is a schematic cross-sectional diagram of the semiconductor structure after a second conductive layer structure is formed in some embodiments.

As shown in FIGS. 11 and 12, in some embodiments, the method for manufacturing the semiconductor structure further includes:

S602, an etching barrier layer is formed on the first conductive layer structure.

Specifically, the etching barrier layer 302, such as a silicon nitride layer, is formed on the first conductive layer structure 206. In some embodiments, a lower surface of the etching barrier layer 302 is flush with the upper surface of the first conductive layer structure 206.

S604, a second isolation dielectric layer is formed on the etching barrier layer.

Specifically, a second isolation dielectric layer 304, such as a silicon oxide layer, is formed on the etching barrier layer 302. In some embodiments, a lower surface of the second isolation dielectric layer 304 is flush with an upper surface of the etching barrier layer 302.

S606, at least one second conductive layer structure is formed in the second isolation dielectric layer.

The at least one second conductive layer structure 306 is formed in the second isolation dielectric layer 304, and a lateral size of a lower surface of the second conductive layer structure 306 is greater than a lateral size of an upper surface of the first conductive layer structure 206, that is, a length of the lower surface of the second conductive layer structure 306 in the first direction is greater than a length of the upper surface of the first conductive layer structure 206 in the first direction.

Specifically, in a first step, a second photoresist mask pattern is formed on the second isolation dielectric layer 304, a projection of an opening of the second photoresist mask pattern on the substrate 102 encloses and covers the conductive layer 210, and a distance between a side wall of the opening of the second photoresist mask pattern and the side wall of the conductive layer 210 is greater than or equal to the first preset value. In a second step, the second isolation dielectric layer 304 and the etching barrier layer 302 are patterned by the second photoresist mask pattern as a mask, and at least one second trench 308 exposing an upper surface and a part of side walls of the first conductive layer structure 206 is formed in the second isolation dielectric layer, and a distance between a bottom side wall of the second trench 308 and an exposed side wall of the first conductive layer structure 206 is the first preset value, and a distance between a bottom of the second trench 308 and an upper surface of the first conductive layer structure is the second preset value. In a third step, the second trench 308 is filled to form the second conductive layer structure 306. In this case, a cross-sectional diagram of the semiconductor structure is as shown in FIG. 12 (for example, the second trench 308 in FIG. 12 is an inverted trapezoidal trench). Steps and processes for forming the second conductive layer structure 306 are similar to those of the first conductive layer structure 206, and will not be repeated here.

In some embodiments, N conductive layer structures are formed on the second conductive layer structure 306, and a lateral size of a lower surface of an Nth conductive layer structure is greater than a lateral size of an (N−1)th conductive layer structure; that is, a length of the lower surface of the Nth conductive layer structure in the first direction is greater than a length of the (N−1)th conductive layer structure in the first direction; and N is greater than or equal to 3.

In some embodiments, some embodiments of the present disclosure further provide a semiconductor structure, the semiconductor structure including:

at least one conductive layer structure, the at least one conductive layer structure being obtained by the method for manufacturing the semiconductor structure according to any one above.

In the semiconductor structure in some embodiments of the present disclosure, the trench exposing the upper surface and the part of side walls of the at least one conductive structure is formed in the first isolation dielectric layer on the substrate, and then the trench is filled to form the first conductive layer structure, and the distance between the side wall of the trench and the side wall of the conductive structure is the first preset value, and the distance between the bottom of the trench and the upper surface of the conductive structure is the second preset value, so that the first conductive layer structure can completely fill the trench and completely contact the conductive structure, and contact areas between the first conductive layer structure and the conductive structure are increased, and a contact resistance is reduced; in addition, a contact surface between the first conductive layer structure and the conductive structure is an inverted plug-type structure, and contact stability between the first conductive layer structure and the conductive structure is increased.

It should be understood that although the steps in the flowchart of FIG. 1 are displayed in sequence as indicated by the arrows, these steps are not necessarily executed in sequence as indicated by the arrows. Unless explicitly specified herein, these steps are not performed in strict sequence, and these steps may be performed in other sequences. Furthermore, at least a part of the steps in FIG. 1 may include a plurality of steps or a plurality of stages. These steps or stages are not necessarily executed at the same time, but may be executed at different times. The execution sequence of these steps or stages is not necessarily executed in sequence, and may be executed in turn or alternately with at least a part of the other steps, or steps or stages of other steps.

Various technical features of the described embodiments can be combined in any way, and in order to make the description brief, all possible combinations of the technical features of the described embodiments are not described. However, as long as the combinations of these technical features are not contradictory, all the combinations should be considered to belong to the scope disclosed in the description.

The embodiments above merely represent several embodiments of the present disclosure, and the description thereof is specific and detailed, but the specific and detailed description cannot be understood as limiting the patent scope of some embodiments of the present disclosure. It should be noted that for a person of ordinary skill in the art, several modifications and improvements can be made without departing from the concept of some embodiments of the present disclosure, and all these modifications and improvements belong to the scope of protection of some embodiments of the present disclosure. Therefore, the scope of protection of some embodiments of the present disclosure shall be subject to the appended claims.

What is claimed is:

1. A method for manufacturing a semiconductor structure, comprising:
providing a substrate, an interlayer dielectric layer being formed on the substrate and at least one conductive structure located in the interlayer dielectric layer;
forming a first isolation dielectric layer on the interlayer dielectric layer and the at least one conductive structure;
forming at least one trench in the first isolation dielectric layer, one of the trench exposing an upper surface and a part of side walls of the at least one conductive structure; and
filling the trench to form a first conductive layer structure;
wherein a distance between a bottom side wall of the trench and an exposed side wall of the conductive structure is a first preset value, and the bottom side wall of the trench and the exposed side wall of the conductive structure are on a same side, and a distance between a bottom of the trench and the upper surface of the conductive structure is a second preset value.

2. The method according to claim 1, wherein the first preset value is not less than 3 nm and not greater than 10 nm.

3. The method according to claim 1, wherein the second preset value is not less than 1 nm and not greater than 20 nm.

4. The method according to claim 1, wherein the interlayer dielectric layer and the first isolation dielectric layer comprise silicon oxide material layers respectively.

5. The method according to claim 1, wherein a distance between bottom side walls of the trench is not greater than a distance between top side walls of the trench.

6. The method according to claim 5, wherein the trench at least comprise one of an inverted trapezoidal trench or a rectangular trench.

7. The method according to claim 1, wherein forming the at least one trench in the first isolation dielectric layer comprises:
forming a photoresist mask pattern on the first isolation dielectric layer, wherein a projection of a opening of the photoresist mask pattern on the substrate covers the conductive structure, and a distance between a side wall of the opening of the photoresist mask pattern and a side wall of the conductive structure in a direction is greater than or equal to the first preset value, the direction is parallel to a surface of the substrate; and
patterning the first isolation dielectric layer by the photoresist mask pattern as a mask to form the at least one trench in the first isolation dielectric layer.

8. The method according to claim 7, wherein before forming the photoresist mask pattern on the first isolation dielectric layer, the method further comprises:
forming a mask layer on the first isolation dielectric layer; and
patterning the first isolation dielectric layer by the photoresist mask pattern as the mask comprises:
patterning the mask layer by the photoresist mask pattern as the mask, so as to obtain a mask pattern; and
patterning the first isolation dielectric layer by the mask pattern as a mask, so as to obtain the at least one trench.

9. The method according to claim 8, wherein patterning the mask layer by the photoresist mask pattern as the mask further comprises:
removing the photoresist mask pattern; and
patterning the first isolation dielectric layer by the mask pattern as the mask comprises:
removing the mask pattern.

10. The method according to claim 8, wherein the mask layer comprises a spin on hard mask layer and a silicon oxynitride layer stacked in sequence on the first isolation dielectric layer; and
forming the mask layer on the first isolation dielectric layer comprises:
forming the spin on hard mask layer on the first isolation dielectric layer; and
forming the silicon oxynitride layer on an upper surface of the spin on hard mask layer.

11. The method according to claim 1, wherein the first conductive layer structure comprises a diffusion barrier layer and a conductive layer; and filling the trench to form the first conductive layer structure comprises:
forming the diffusion barrier layer in the trench, the diffusion barrier layer covering side walls and the bottom of the trench, and the upper surface and the part of side walls of the conductive structure exposed by the trench; and
forming the conductive layer on an upper surface of the diffusion barrier layer, the conductive layer filling up the trench.

12. The method according to claim 11, wherein an upper surface of the conductive layer in the trench is higher than an upper surface of the first isolation dielectric layer; and after forming the conductive layer on the upper surface of the diffusion barrier layer, the method further comprises:
performing a thinning treatment, until the upper surface of the conductive layer is flush with the upper surface of the first isolation dielectric layer.

13. The method according to claim 11, wherein the diffusion barrier layer at least comprise one of a titanium nitride material layer, a tantalum nitride material layer or a tungsten nitride material layer, and the conductive layer and the conductive structure at least comprise one of a copper material layer, a tungsten material layer or an aluminum material layer, or the conductive layer at least comprises one of the copper material layer, the tungsten material layer or the aluminum material layer, or the conductive structure at least comprises one of the copper material layer, the tungsten material layer or the aluminum material layer.

14. The method according to claim 1, further comprising:
forming an etching barrier layer on the first conductive layer structure;
forming a second isolation dielectric layer on the etching barrier layer; and
forming at least one second conductive layer structure in the second isolation dielectric layer, wherein a lateral size of a lower surface of the second conductive layer structure is greater than a lateral size of an upper surface of the first conductive layer structure.

15. The method according to claim 14, wherein N conductive layer structures are formed on the second conductive layer structure, and a lateral size of a lower surface of an Nth conductive layer structure is greater than a lateral size of an upper surface of an (N−1)th conductive layer structure;
wherein N is greater than or equal to 3.

16. The method according to claim 1, wherein the trench is formed by a dry etching process, and a process gas of the dry etching process comprises a fluorine-based gas.

17. A semiconductor structure, comprising:
at least one conductive layer structure, the at least one conductive layer structure being obtained by the method for manufacturing the semiconductor structure according to claim 1.

18. The method according to claim 2, further comprising:
forming an etching barrier layer on the first conductive layer structure;
forming a second isolation dielectric layer on the etching barrier layer; and
forming at least one second conductive layer structure in the second isolation dielectric layer, wherein a lateral size of a lower surface of the second conductive layer structure is greater than a lateral size of an upper surface of the first conductive layer structure.

19. The method according to claim 3, further comprising:
forming an etching barrier layer on the first conductive layer structure;
forming a second isolation dielectric layer on the etching barrier layer; and
forming at least one second conductive layer structure in the second isolation dielectric layer, wherein a lateral size of a lower surface of the second conductive layer structure is greater than a lateral size of an upper surface of the first conductive layer structure.

20. The method according to claim 4, further comprising:
forming an etching barrier layer on the first conductive layer structure;
forming a second isolation dielectric layer on the etching barrier layer; and
forming at least one second conductive layer structure in the second isolation dielectric layer, wherein a lateral size of a lower surface of the second conductive layer structure is greater than a lateral size of an upper surface of the first conductive layer structure.
